(19) United States
(12) Patent Application Publication
(10) Pub. No.: US 2025/0305773 A1
(43) Pub. Date: Oct. 2, 2025

(54) VAPOR CHAMBER AND SEMICONDUCTOR PACKAGE INCLUDING THE SAME

(71) Applicant: SAMSUNG ELECTRONICS CO., LTD., Suwon-si (KR)

(72) Inventors: Youngjoon KOH, Suwon-si (KR); Jae Choon KIM, Suwon-si (KR); Sung-Ho MUN, Suwon-si (KR)

(73) Assignee: SAMSUNG ELECTRONICS CO., LTD., Suwon-si (KR)

(21) Appl. No.: 18/920,442

(22) Filed: Oct. 18, 2024

(30) Foreign Application Priority Data
Mar. 29, 2024 (KR) 10-2024-0043497

(51) Int. Cl. F28D 15/04; H01L 23/427; H01L 23/433

(52) U.S. Cl. CPC F28D 15/046; H01L 23/427; H01L 23/433

(57) ABSTRACT

A vapor chamber according to an embodiment of the present disclosure includes: a housing including an upper plate and a lower plate coupled to the upper plate; a first wick structure disposed above an inner upper surface of the upper plate; a second wick structure disposed above an inner lower surface of the lower plate; a first deformation prevention structure disposed between the upper plate and the first wick structure; a second deformation prevention structure disposed between the lower plate and the second wick structure; and pillars disposed inside the housing and penetrate the first wick structure, the second wick structure, the first deformation prevention structure, and the second deformation prevention structure.

### CROSS-REFERENCE TO RELATED APPLICATION

This application is based on and claims priority to Korean Patent Application No. 10-2024-0043497, filed at the Korean Intellectual Property Office on Mar. 29, 2024, the entire contents of which are incorporated herein by reference.

### BACKGROUND

### 1. Field

The present disclosure relates to a vapor chamber and a semiconductor package including the same.

### 2. Description of Related Art

As new technologies such as artificial intelligence (AI), high-performance computing (HPC), and autonomous vehicles are developed, large-area package products (e.g., a 2.5 D package) are being manufactured to mount many CPUs and memory chips within one semiconductor package. Various heat dissipation technologies are being researched to prevent performance of the semiconductor package from being deteriorated due to heat generated when high-performance products are used.

A vapor chamber has advantages of using a heat of vaporization absorbed when a liquid becomes a gas to release the heat generated from the product, thereby reducing a risk of a hot spot through large-area heat dissipation, and increasing an allowable power of the product.

### SUMMARY

Provided is a semiconductor package with improved heat dissipation characteristics as a result of the inclusion of a vapor chamber with minimized thermal deformation.

Also provided is a vapor chamber and a semiconductor package with mechanical stability.

According to an aspect of the disclosure, a vapor chamber includes: a housing comprising an upper plate and a lower plate coupled to the upper plate; a first wick structure on an inner upper surface of the upper plate; a second wick structure on an inner lower surface of the lower plate; a first deformation prevention structure between the upper plate and the first wick structure; a second deformation prevention structure between the lower plate and the second wick structure; and a pillar inside the housing, wherein the pillar penetrates the first wick structure, the second wick structure, the first deformation prevention structure, and the second deformation prevention structure.

According to an aspect of the disclosure, a vapor chamber includes: a housing comprising an upper plate and a lower plate coupled to the upper plate; a first wick structure on an inner upper surface of the upper plate; a second wick structure on an inner lower surface of the lower plate; a first deformation prevention structure between the upper plate and the first wick structure; a second deformation prevention structure between the lower plate and the second wick structure; a pillar inside the housing, wherein the pillar penetrates the first wick structure and the second wick structure; a first adhesive member between the first deformation prevention structure and the pillar; and a second adhesive member between the second deformation prevention structure and the pillar.

According to an aspect of the disclosure, a semiconductor package includes: a substrate; a semiconductor chip on the substrate and connected to the substrate; a vapor chamber on the semiconductor chip; and a thermal interface material between the semiconductor chip and the vapor chamber, wherein the vapor chamber comprises: a housing comprising an upper plate and a lower plate coupled to the upper plate; a first wick structure on an inner upper surface of the upper plate; a second wick structure on an inner lower surface of the lower plate; a first deformation prevention structure between the upper plate and the first wick structure; a second deformation prevention structure between the lower plate and the second wick structure; a pillar inside the housing, wherein the pillar is extends from the upper plate to the lower plate and penetrates at least the first wick structure and the second wick structure; and a third wick structure that surrounds a side surface of the pillar at a level between the first wick structure and the second wick structure.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a cross-sectional view of a vapor chamber according to an embodiment;

FIG. 2 is a plan view of the vapor chamber of FIG. 1 cut in a direction (or a line) I-I′;

FIG. 3 is an exemplary enlarged view of a region A of FIG. 1;

FIG. 4 is an exemplary enlarged view of a region B of FIG. 1;

FIG. 5 is an exemplary enlarged view of the region A of FIG. 1;

FIG. 6 is an exemplary enlarged view of the region B of FIG. 1;

FIG. 7 is a cross-sectional view of a state before the vapor chamber of FIG. 1 is assembled;

FIG. 8 is a cross-sectional view of a vapor chamber according to a comparative example;

FIG. 9 is a view for describing thermal deformation of the vapor chamber according to the comparative example;

FIG. 10 is a cross-sectional view of a semiconductor package including the vapor chamber according to the comparative example;

FIG. 11 is a cross-sectional view of a vapor chamber according to an embodiment;

FIG. 12 is a cross-sectional view of a vapor chamber according to an embodiment;

FIG. 13 is a cross-sectional view of a vapor chamber according to an embodiment;

FIG. 14 is a cross-sectional view of a vapor chamber according to an embodiment;

FIG. 15 is a cross-sectional view of a vapor chamber according to an embodiment; and

FIG. 16 is a cross-sectional view of a semiconductor package according to an embodiment.

### DETAILED DESCRIPTION

Embodiments of the present disclosure will be described more fully hereinafter with reference to the accompanying drawings so that those skilled in the art may implement the embodiments. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

Throughout the specification, when a part is “connected” to another part, it includes not only a case where the part is “directly connected” but also a case where the part is “indirectly connected” with another part in between. In a similar sense, this includes being “physically connected” as well as being “electrically connected”.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

In addition, throughout the specification, sequential numbers such as 1st and 2nd are used to distinguish a certain component from another component that is the same or similar to the same, and are not necessarily intended to refer to a specific component. Accordingly, a component referred to as a first component in a specific portion of the specification may be referred to as a second component in another portion of the specification.

Additionally, throughout the specification, a singular reference to a component includes references to a plurality of these components, unless specifically stated to the contrary.

As used herein, the expressions “at least one of a, b or c” and “at least one of a, b and c” indicate “only a,” “only b,” “only c,” “both a and b,” “both a and c,” “both b and c,” and “all of a, b, and c.”

Hereinafter, a vapor chamber and a semiconductor package including the same according to the present disclosure will be described in detail with reference to the drawings.

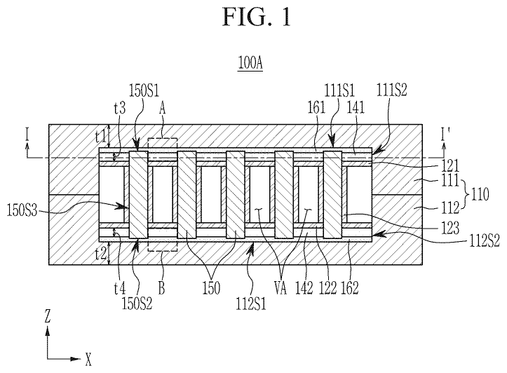

FIG. 1 is a cross-sectional view of a vapor chamber according to an embodiment.

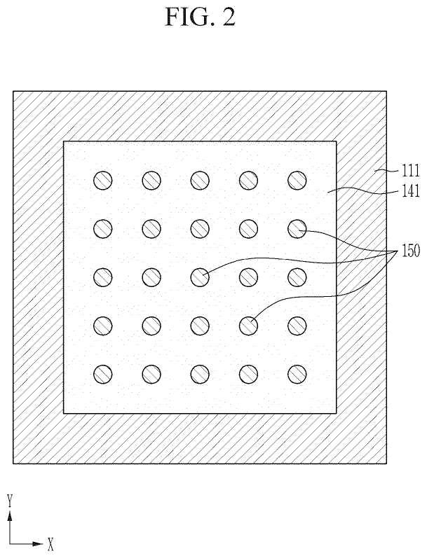

FIG. 2 is a plan view of the vapor chamber of FIG. 1 cut in a direction (or a line) I-I′.

The vapor chamber 100A may include a housing 110 including an upper plate 111 and a lower plate 112 coupled to each other, a first wick structure 121, a second wick structure 122, a first deformation prevention structure 141, a second deformation prevention structure 142, and pillars 150, and may further include one or more of a first adhesive member 161, a second adhesive member 162, and a third wick structure 123.

The housing 110 may have an appearance of the vapor chamber 100A, and may be manufactured by coupling the upper plate 111 to the lower plate 112. The pillars 150 or the like may be accommodated in the housing 110, and a space for moving a working fluid may exist inside the housing 110.

The upper plate 111 may have an inner surface including an inner upper surface 111S1 and an inner side surface 111S2, and may have a shape in which a lower side thereof is open. A thickness t1 on the inner upper surface 111S1 of the upper plate 111 may be 0.5 mm to 2 mm. In the present disclosure, the thickness means a thickness along a Z-direction (Z).

Similarly, the lower plate 112 may have an inner surface including an inner lower surface 112S1 and an inner side surface 112S2, and may have a shape in which an upper side thereof is open. A thickness t2 on the inner lower surface 112S1 of the lower plate 112 may be 0.5 mm to 2 mm.

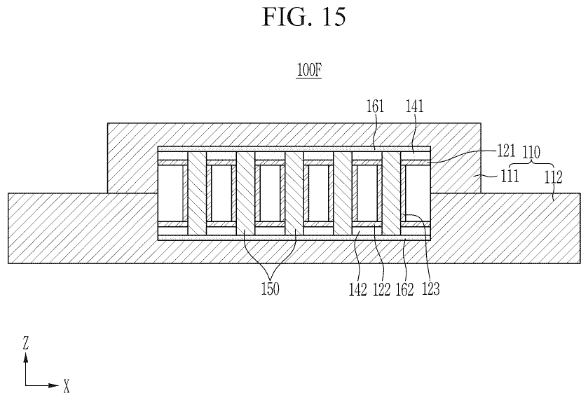

The inner upper surface 111S1 and the inner side surface 111S2 of the upper plate 111 and the inner lower surface 112S1 and the inner side surface 112S2 of the lower plate 112 may be connected to each other to form an inner surface of the housing 110 by coupling the upper plate 111 to the lower plate 112. The upper plate 111 and the lower plate 112 may form a plat-type housing 110 by having shapes corresponding to each other, but the present disclosure is not limited thereto, and they may have different shapes as described below with reference to FIG. 15.

A contact area between the upper plate 111 and the lower plate 112 may be appropriately adjusted to be attached to each other. For example, widths of a contact area between the upper plate 111 and the lower plate 112 along an X-direction (X) and a Y-direction (Y) may be 1 mm or more.

A material with a high thermal conductivity may be used as a material of each of the upper plate 111 and the lower plate 112, and for example, a metal material such as copper (Cu), aluminum (Al), titanium (Ti), nickel (Ni), or an alloy thereof may be used as the material of each of the upper plate 111 and the lower plate 112. Additionally, the material of each of the upper plate 111 and the lower plate 112 may be the same or different.

Each of the upper plate 111 and the lower plate 112 may be manufactured by injection molding, mold molding, etching molding, or the like.

A method of coupling the upper plate 111 to the lower plate 112 is not particularly limited. For example, each of the upper plate 111 and the lower plate 112 may be formed of copper (Cu) to be coupled as Cu—Cu diffusion bonding. During the diffusion bonding, components bonded to each other may be bonded in contact with each other. As another example, the upper plate 111 and the lower plate 112 may be coupled through an adhesive member such as a separate bonding paste, a separate adhesive, a separate adhesive film, or the like interposed between them.

Each of the first wick structure 121, the second wick structure 122, and the third wick structure 123 may function as an absorption material of a working fluid.

The first wick structure 121 may be disposed on the inner upper surface 111S1 of the upper plate 111. However, the first wick structure 121 is not disposed directly on the inner upper surface 111S1 of the upper plate 111, and the first deformation prevention structure 141 may exist between the first wick structure 121 and the inner upper surface 111S1 of the upper plate 111. Additionally, the first adhesive member 161 may further exist between the first wick structure 121 and the inner upper surface 111S1 of the upper plate 111. The first wick structure 121 may contact the inner side surface 111S2 of the upper plate 111, but the present disclosure is not limited thereto.

The first wick structure 121 may be formed directly on the first deformation prevention structure 141 through a deposition process such as a CVD, a PVD, or the like. In this case, the first wick structure 121 may contact the first deformation prevention structure 141. Alternatively, the first wick structure 121 may be attached on the first deformation prevention structure 141 through an adhesive member such as a bonding paste, an adhesive, an adhesive film, or the like. In this case, a separate adhesive member may be interposed between the first wick structure 121 and the first deformation prevention structure 141.

The second wick structure 122 may be disposed on the inner lower surface 112S1 of the lower plate 112. However, the second wick structure 122 is not disposed directly on the inner lower surface 112S1 of the lower plate 112, and the second deformation prevention structure 142 may exist between the second wick structure 122 and the inner lower surface 112S1 of the lower plate 112. Additionally, the second adhesive member 162 may further exist between the second wick structure 122 and the inner lower surface 112S1 of the lower plate 112. The second wick structure 122 may contact the inner side surface 112S2 of the lower plate 112, but the present disclosure is not limited thereto.

The second wick structure 122 may be formed directly on the second deformation prevention structure 142 through a deposition process such as CVD, a PVD, or the like. In this case, the second wick structure 122 may be in contact with the second deformation prevention structure 142. Alternatively, the second wick structure 122 may be attached on the second deformation prevention structure 142 through an adhesive member such as a bonding paste, an adhesive, an adhesive film, or the like. In this case, a separate adhesive member may be interposed between the second wick structure 122 and the second deformation prevention structure 142.

The third wick structure 123 may surround side surfaces of the pillars 150 at a level between the first wick structure 121 and the second wick structure 122. The third wick structure 123 may be formed directly on side surfaces 150S3 of the pillars 150 through Cu—Cu diffusion bonding or the like.

The first wick structure 121, the second wick structure 122, and the third wick structure 123 may constitute a vapor area VA, and a working fluid in a vapor state may exist at the vapor area VA.

A metal mesh (e.g., a copper (Cu) mesh or an aluminum (Al) mesh), a carbon nanoparticle, a carbon nanotube, a sintered particle, a conductive polymer, or the like may be used as a material of each of the first wick structure 121, the second wick structure 122, and the third wick structure 123.

The first deformation prevention structure 141 may be disposed between the upper plate 111 and the first wick structure 121. The first deformation prevention structure 141 may be coupled to the upper plate 111 to minimize thermal deformation of the upper plate 111.

The first deformation prevention structure 141 may be attached to the upper plate 111 through the first adhesive member 161 interposed between the first deformation prevention structure 141 and the upper plate 111. For example, if the first deformation prevention structure 141 is made of ceramic and the upper plate 111 is made of copper (Cu) so that direct coupling between them is difficult, they may be coupled to each other through the first adhesive member 161. However, depending on materials or the like of the first deformation prevention structure 141 and the upper plate 111, they may be coupled in contact with each other.

The first deformation prevention structure 141 may contact the inner side surface 111S2 of the upper plate 111 like the first wick structure 121, but the present disclosure is not limited thereto.

Similarly, the second deformation prevention structure 142 may be disposed between the lower plate 112 and the second wick structure 122. The second deformation prevention structure 142 may be coupled to the lower plate 112 to minimize thermal deformation of the lower plate 112.

The second deformation prevention structure 142 may be attached to the lower plate 112 through the second adhesive member 162 interposed between the second deformation prevention structure 142 and the lower plate 112. For example, if the second deformation prevention structure 142 is made of ceramic and the lower plate 112 is made of copper (Cu) so that direct coupling between them is difficult, they may be bonded to each other through the second adhesive member 162. However, depending on materials or the like of the second deformation prevention structure 142 and the lower plate 112, they may be coupled in contact with each other.

The second deformation prevention structure 142 may be in contact with the inner side surface 112S2 of the lower plate 112 like the second wick structure 122, but the present disclosure is not limited thereto.

A material resistant to thermal deformation may be used as a material of each of the first deformation prevention structure 141 and the second deformation prevention structure 142 to minimize mechanical deformation between each of the first deformation prevention structure 141 and the second deformation prevention structure 142 and the vapor chamber 100A.

In an embodiment, a material having a large Young's modulus may be used as the material of each of the first deformation prevention structure 141 and the second deformation prevention structure 142. The Young's modulus of each of the first deformation prevention structure 141 and the second deformation prevention structure 142 may be at least greater than a Young's modulus of each of the upper plate 111 and the lower plate 112. For example, the Young's modulus of each of the first deformation prevention structure 141 and the second deformation prevention structure 142 may be 1.5 times or more, 2 times or more, 2.5 times or more, or 3 times or more than the Young's modulus of each of the upper plate 111 and the lower plate 112.

In addition, a material with a high thermal conductivity may be used as the material of each of the first deformation prevention structure 141 and the second deformation prevention structure 142 in order not to impede a heat dissipation characteristic of the vapor chamber 100A. A thermal conductivity of each of the first deformation prevention structure 141 and the second deformation prevention structure 142 may be similar to or higher than a thermal conductivity of each of the upper plate 111 and the lower plate 112. For example, the thermal conductivity of each of the first deformation prevention structure 141 and the second deformation prevention structure 142 may be 80% or more of the thermal conductivity of each of the upper plate 111 and the lower plate 112. In one or more embodiments, the thermal conductivity of each of the first deformation prevention structure 141 and the second deformation prevention structure 142 may be 80% or more, 85% or more, 90% or more, or 95% or more of the thermal conductivity of each of the upper plate 111 and the lower plate 112.

For example, if copper is used as the material of each of the upper plate 111 and the lower plate 112, a material having a higher Young's modulus than that of copper and having a thermal conductivity similar to or higher than that of copper may be used as the material of each of the first deformation prevention structure 141 and the second deformation prevention structure 142.

Each of the first deformation prevention structure 141 and the second deformation prevention structure 142 may include ceramic, and for example, it may include silicon carbide (SiC) such as 4H-SiC. A Young's modulus of 4H-SiC may be about 390 Gpa to 690 Gpa, a thermal conductivity of 4H-SiC may be about 330 W/mK to 490 W/mK, and 4H-SiC may have a Young's modulus greater than a Young's modulus (e.g., about 110 Gpa) of copper and may have a thermal conductivity greater than a thermal conductivity (e.g., about 385 W/mK) of copper. Thus, 4H-SiC may be suitable as the material of each of the first deformation prevention structure 141 and the second deformation prevention structure 142. However, the material of each of the first deformation prevention structure 141 and the second deformation prevention structure 142 is not limited to ceramic, and another material (e.g., diamond) that is resistant to thermal deformation and has an excellent thermal conductivity may be appropriately selected and used as necessary.

A thickness t3 of the first deformation prevention structure 141 may be 50% to 100% of the thickness t1 of the upper plate 111 above the inner upper surface 111S1 of the upper plate 111. Similarly, a thickness t4 of the second deformation prevention structure 142 may be 50% to 100% of the thickness t2 of the lower plate 112 above the inner lower surface 112S1 of the lower plate 112. For example, the thickness t3 of the first deformation prevention structure 141 and the thickness t4 of the second deformation prevention structure 142 may be 0.25 mm to 2 mm.

If the thicknesses of the first deformation prevention structure 141 and the second deformation prevention structure 142 are too thin, it may be difficult to prevent thermal deformation of the vapor chamber 100A, and if the thicknesses of the first deformation prevention structure 141 and the second deformation prevention structure 142 are too thick, an entire thickness of the vapor chamber 100A may increase. Therefore, the thicknesses of the first deformation prevention structure 141 and the second deformation prevention structure 142 may be adjusted to the above-described range.

The first adhesive member 161 may be disposed between the upper plate 111 and the first deformation prevention structure 141 to attach them to each other. A material (for example, a bonding paste, an adhesive, an adhesive film, or the like) having adhesiveness may be used as a material of the first adhesive member 161.

The first adhesive member 161 may contact the inner side surface 111S2 of the upper plate 111 like the first wick structure 121 and/or the first deformation prevention structure 141, but the present disclosure is not limited thereto.

Similarly, the second adhesive member 162 may be disposed between the lower plate 112 and the second deformation prevention structure 142 to attach them to each other. A material (for example, a bonding paste, an adhesive, an adhesive film, or the like) having adhesiveness may be used as a material of the second adhesive member 162.

The second adhesive member 162 may be in contact with the inner side surface 112S2 of the lower plate 112 like the second wick structure 122 and/or the second deformation prevention structure 142, but the present disclosure is not limited thereto.

In an embodiment, the first adhesive member 161 may extend to be disposed between the upper plate 111 and the pillar 150 and/or the second adhesive member 162 may extend to be disposed between the lower plate 112 and the pillar 150.

In this case, the first adhesive member 161 may surround (or wrap) a region of the side surface 150S3 adjacent to one end portion 150S1 of the pillar 150, or the second adhesive member 162 may surround a region of the side surface 150S3 adjacent to the other end portion 150S2 that is an end portion opposite to the one end portion 150S1 of the pillar 150. If the pillars 150 are attached to the first adhesive member 161 and the second adhesive member 162, the pillar 150 may dig into the inside of the first adhesive member 161 and/or the second adhesive member 162 due to a pressure applied to the adhesive member.

In an embodiment, the pillar 150 may be inserted into the deformation prevention structures 141 and 142 to be attached to the adhesive members 161 and 162. Thus, an adhesive area between the pillar 150 and the adhesive members 161 and 162 may be increased, and mechanical stability between the pillar 150 and the deformation prevention structures 141 and 142 may be improved. Additionally, a manufacturing cost of a case in which the adhesive members 161 and 162 are used may be reduced compared with that of a case in which the pillar 150 is directly bonded to the upper plate 111 and the lower plate 112.

The pillars 150 may be disposed inside the housing 110. The pillars 150 may be disposed inside the housing 110 in the Z-direction (Z) that is a direction from the upper plate 111 to the lower plate 112. Accordingly, one end portion 150S1 of the pillar 150 may face the upper plate 111, and the other end portion 150S2 of the pillar 150 may face the lower plate 112.

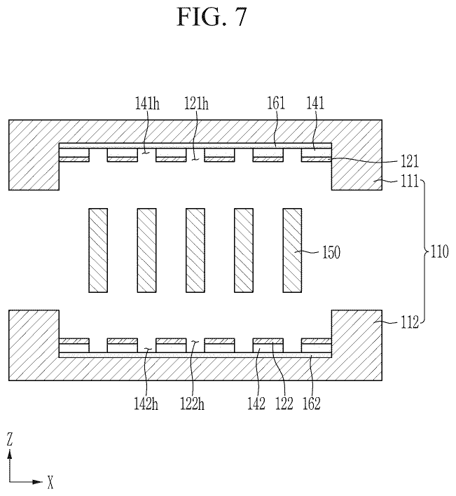

The pillars 150 may penetrate at least the first wick structure 121 and the second wick structure 122, and may further penetrate the first deformation prevention structure 141 and the second deformation prevention structure 142. As described below with reference to FIG. 7, the pillar 150 may be inserted into a hole 121h of the first wick structure 121, a hole 122h of the second wick structure 122, a hole 141h of the first deformation prevention structure 141, and a hole 142h of the second deformation prevention structure 142 in a fitting manner to have a structure penetrating the hole 121h, the hole 122h, the hole 141h, and the hole 142h.

A material with a high thermal conductivity may be used as a material of the pillar 150, and for example, a metal material such as copper (Cu), aluminum (Al), titanium (Ti), nickel (Ni), or an alloy thereof may be used as the material of the pillar 150.

The pillar 150 may have a cylinder pillar shape, but the present disclosure is not limited thereto, and the pillar 150 may have another shape such as a quadrangle pillar shape or a hexagon pillar shape.

A space where the pillars 150 are spaced apart from each other may be defined as the vapor area VA, and the vapor area VA may serve as a path for moving a working fluid. The working fluid may be purified water, but the present disclosure is not limited thereto.

The number of the pillars 150 is not particularly limited, and may be appropriately designed within a range in which the number of the pillars 150 may have the vapor area VA that sufficiently secures a movement path of the working fluid and the number of the pillars 150 may secure mechanical stability of the vapor chamber 100A.

A thermal conductivity of the vapor chamber 100A along the X-direction (X) and a thermal conductivity of the vapor chamber 100A along the Y-direction (Y) may be greater than a thermal conductivity of the vapor chamber 100A along the Z-direction (Z). For example, the thermal conductivity of the vapor chamber 100A along the Z-direction (Z) may be about 385 W/mK, and the thermal conductivity of the vapor chamber 100A along the X-direction (X) and the thermal conductivity of the vapor chamber 100A along the Y-direction (Y) may be 2000 to 3000 W/mK. The vapor chamber 100A may have a higher thermal conductivity along each of the X-direction (X) and the Y-direction (Y) compared with that of a metal plate type heat dissipation structure such as copper (Cu), and may minimize a hot spot.

On the other hand, the vapor chamber may be attached to a product such as a semiconductor chip 300 through a thermal interface material (TIM) or the like. In this case, as contact interfaces between the vapor chamber, the thermal interface material, and the semiconductor chip is flat and thermal deformation of the vapor chamber is minimized, a thermal insulation effect by air collection may decrease so that a heat dissipation characteristic of the semiconductor package is advantageous. Therefore, the present disclosure may improve performance of the semiconductor chip by providing the vapor chamber having the mechanical stability and an excellent heat dissipation characteristic.

On the other hand, other exemplary methods for planarizing the contact interfaces between the vapor chamber, the thermal interface material, and the semiconductor chip may be considered.

In one of the exemplary methods in which flatness is increased by grinding the upper plate 111 and the lower plate 112, additional thermal deformation in a heating process of a packaging process may not be prevented. Therefore, detachment between the vapor chamber, the thermal interface material, and the semiconductor chip may occur due to a difference in flatness of the contact interfaces between the vapor chamber, the thermal interface material, and the semiconductor chip. The detachment between the vapor chamber, the thermal interface material, and the semiconductor chip may cause a problem of deteriorating a heat dissipation characteristic of the semiconductor package due to occurrence of a heat spot risk caused by formation of a non-uniform heat path and an increase in a heat resistance caused by collected air.

In another one of the exemplary methods in which the upper plate 111 and the lower plate 112 are designed to be thick, there may be a problem in which compatibility with package assembly process equipment is difficult and a thickness of an entire product is increased.

In another one of the exemplary methods, mechanical stability of the vapor chamber may be secured by disposing the pillars 150 more densely. However, in this case, paths for moving a vapor may be insufficient so that the heat dissipation characteristic of the semiconductor package is deteriorated.

According to the present disclosure, thermal deformation of the vapor chamber 100A may be prevented by introducing the deformation prevention structures 141 and 142, and the contact interfaces between the vapor chamber 100A, the thermal interface material, and the semiconductor chip may be maintained flat. In addition, the heat dissipation characteristic of the semiconductor package may be improved by minimizing the heat resistance caused by the collected air, and performance of the semiconductor package may be improved by increasing an allowable power of the semiconductor package. In addition, a stress applied to the semiconductor chip may be reduced by reducing thermal deformation of the vapor chamber 100A so that a damage such as a crack of the semiconductor chip is prevented and reliability is secured.

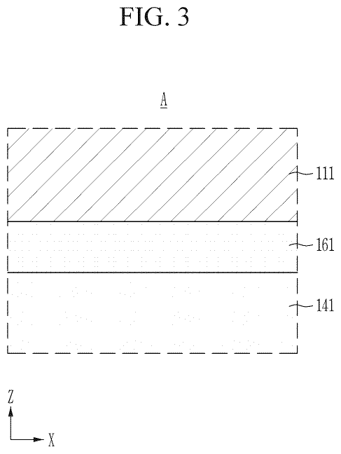

FIG. 3 is an exemplary enlarged view of a region A of FIG. 1.

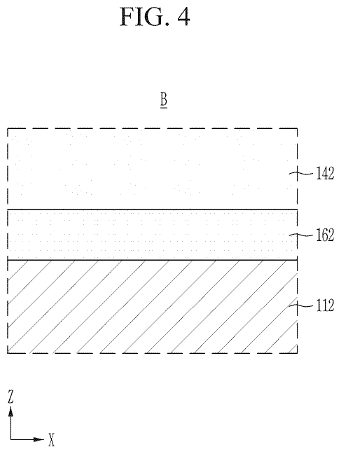

FIG. 4 is an exemplary enlarged view of a region B of FIG. 1.

Referring to FIG. 3 and FIG. 4, one surface of each of the upper plate 111 and the first deformation prevention structure 141 may be substantially flat. Additionally, one surface of each of the lower plate 112 and the second deformation prevention structure 142 may be substantially flat.

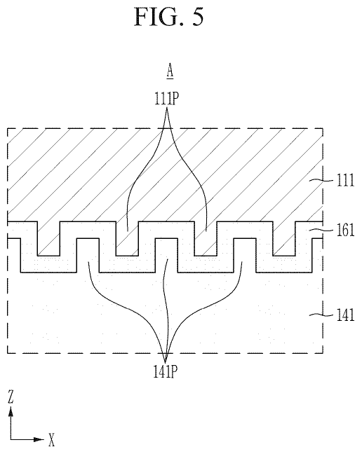

FIG. 5 is an exemplary enlarged view of the region A of FIG. 1.

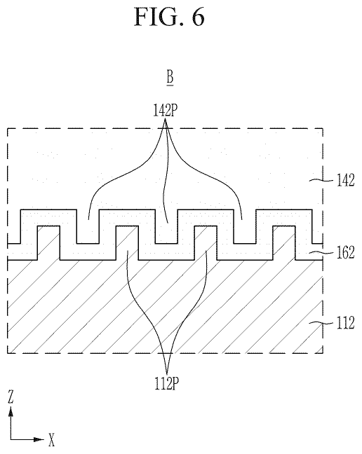

FIG. 6 is an exemplary enlarged view of the region B of FIG. 1.

Referring to FIG. 5, the upper plate 111 may include a plurality of first protruding portions 111P protruding in a direction from the upper plate 111 toward the lower plate 112. Additionally, the first deformation prevention structure 141 may include a plurality of second protruding portions 141P protruding in a direction from the lower plate 112 toward the upper plate 111, and each of the plurality of second protruding portions 141P may be disposed between the plurality of first protruding portions 111P.

Referring to FIG. 6, the lower plate 112 may have a plurality of third protruding portions 112P protruding in the direction from the lower plate 112 toward the upper plate 111. Additionally, the second deformation prevention structure 142 may include a plurality of fourth protruding portions 142P protruding in a direction from the upper plate 111 to the lower plate 112, and the plurality of fourth protruding portions 142P may be disposed between the plurality of third protruding portions 112P.

In an embodiment, a protruding portion may be formed at the upper plate 111 and the first deformation prevention structure 141, so that an adhesive area between each of the upper plate 111 and the first deformation prevention structure 141 and the first adhesive member 161 is increased and an adhesive force between the upper plate 111 and the first deformation prevention structure 141 is increased. In addition, a protruding portion may be formed at the lower plate 112 and the second deformation prevention structure 142, so that an adhesive area between each of the lower plate 112 and the second deformation prevention structure 142 and the second adhesive member 162 is increased and an adhesive force between the lower plate 112 and the second deformation prevention structure 142 is increased.

FIG. 7 is a cross-sectional view of a state before the vapor chamber of FIG. 1 is assembled.

In the drawings, the third wick structure 123 is excluded.

Each of the first wick structure 121, the second wick structure 122, the first deformation prevention structure 141, and the second deformation prevention structure 142 may have a hole for receiving the pillar 150. The pillar 150 may be inserted into the hole 121h of the first wick structure 121, the hole 122h of the second wick structure 122, the hole 141h of the first deformation prevention structure 141, and the hole 142h of the second deformation prevention structure 142 in a fitting manner to have a structure penetrating the hole 121h, the hole 122h, the hole 141h, and the hole 142h.

The hole 121h of the first wick structure 121 and the hole 141h of the first deformation preventing structure 141 may have a region overlapped in the Z-direction (Z), and one end portion 150S1 of the pillar 150 may be inserted into the overlapped region. Diameters or widths of the hole 121h of the first wick structure 121 and the hole 141h of the first deformation prevention structure 141 may be the same, but may be different.

The hole 122h of the second wick structure 122 and the hole 142h of the second deformation preventing structure 142 may have a region overlapped in the Z-direction (Z), and the other end portion 150S2 of the pillar 150 may be inserted into the overlapped region. Diameters or widths of the hole 122h of the second wick structure 122 and the hole 142h of the second deformation prevention structure 142 may be the same, but may be different.

The hole 121h of the first wick structure 121 and the hole 141h of the first deformation prevention structure 141 may be connected to each other to expose at least a partial region of the first adhesive member 161 attached to the upper plate 111. One end portion 150S1 of the pillar 150 may be attached to a region exposed through the hole 121h of the first wick structure 121 of the first adhesive member 161 and the hole 141h of the first deformation prevention structure 141. If the pillar 150 is attached to the first adhesive member 161, the pillar 150 may dig into the inside of the first adhesive member 161 due to a pressure applied to the first adhesive member 161. Accordingly, the first adhesive member 161 may surround a region of the side surface 150S3 adjacent to one end portion 150S1 of the pillar 150.

The hole 122h of the second wick structure 122 and the hole 142h of the second deformation prevention structure 142 may be connected to each other to expose at least a partial region of the second adhesive member 162 attached to the lower plate 112. One end portion 150S1 of the pillar 150 may be attached to a region exposed through the hole 122h of the second wick structure 122 of the second adhesive member 162 and the hole 142h of the second deformation prevention structure 142. If the pillar 150 is attached to the second adhesive member 162, the pillar 150 may dig into the inside of the second adhesive member 162 due to a pressure applied to the second adhesive member 162. Accordingly, the second adhesive member 162 may surround a region of the side surface 150S3 adjacent to the other end portion 150S2 of the pillar 150.

In an embodiment, the pillar 150 may be inserted into the deformation prevention structures 141 and 142 to be attached to the adhesive members 161 and 162. Thus, an adhesive area between the pillar 150 and the adhesive members 161 and 162 may be increased, and mechanical stability between the pillar 150 and the deformation prevention structures 141 and 142 may be improved.

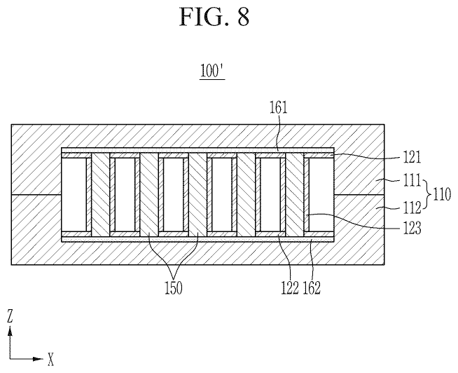

FIG. 8 is a cross-sectional view of a vapor chamber according to a comparative example.

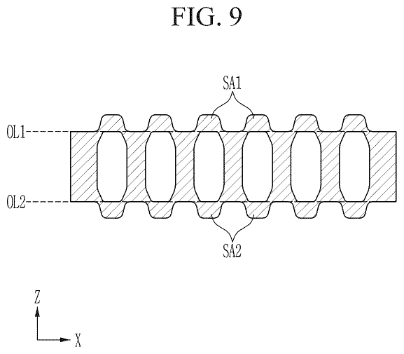

FIG. 9 is a view for describing thermal deformation of the vapor chamber according to the comparative example.

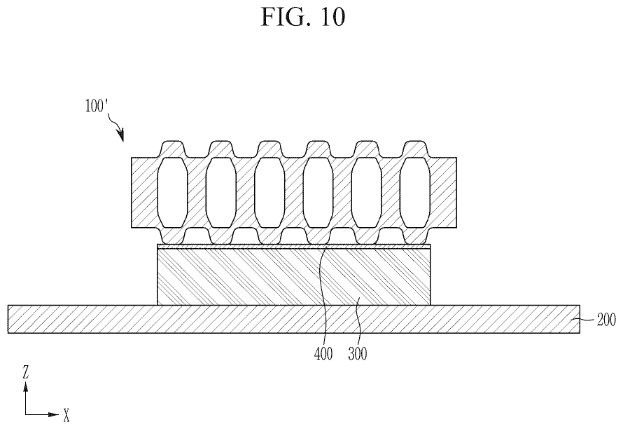

FIG. 10 is a cross-sectional view of a semiconductor package including the vapor chamber according to the comparative example.

The vapor chamber 100′ according to the comparative example may not include a first deformation prevention structure 141 and a second deformation prevention structure 142.

If a heat is transferred to the vapor chamber 100′, an upper plate 111 and a lower plate 112 may not be coupled to pillars 150, and areas SA1 and SA2 swollen by an internal pressure may be formed. For example, the areas SA1 swollen upward from an original level OL1 that is a level before the heat is transferred to the vapor chamber 100′ may be formed at the upper plate 111, and the areas SA2 swollen downward from an original level OL2 may be formed at the lower plate 112.

If the thermally deformed vapor chamber 100′ is attached to a semiconductor chip 300, detachment between the vapor chamber 100′, a thermal interface material 400, and the semiconductor chip 300 may occur. The detachment between the vapor chamber 100′, the thermal interface material 400, and the semiconductor chip 300 may cause a problem of deteriorating a heat dissipation characteristic of the semiconductor package due to occurrence of a heat spot risk caused by formation of a non-uniform heat path and an increase in a heat resistance caused by collected air. Additionally, a stress applied to the semiconductor chip 300 may increase.

On the other hand, according to the present disclosure, thermal deformation of the vapor chamber may be prevented by introducing the deformation prevention structures 141 and 142, and the contact interfaces between the vapor chamber, the thermal interface material, and the semiconductor chip may be maintained flat. In addition, the heat dissipation characteristic of the semiconductor package may be improved by minimizing the heat resistance caused by the collected air, and performance of the semiconductor package may be improved by increasing an allowable power of the semiconductor package. In addition, a stress applied to the semiconductor chip may be reduced by reducing thermal deformation of the vapor chamber 100A so that a damage such as a crack of the semiconductor chip is prevented and reliability is secured.

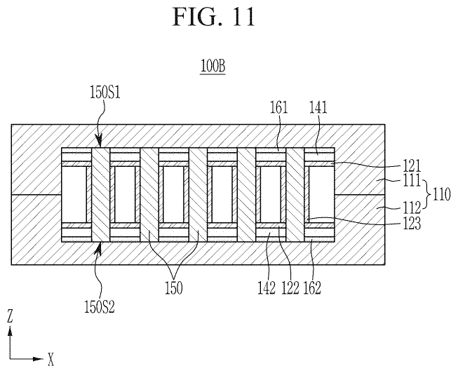

FIG. 11 is a cross-sectional view of a vapor chamber according to an embodiment.

Referring to the drawings, in the vapor chamber 100B, one end portion 150S1 of a pillar 150 may contact an upper plate 111, and the other end portion 150S2 of the pillar 150 may contact a lower plate 112.

If the pillar 150, the upper plate 111, and the lower plate 112 are formed of the same material, they may be coupled by being in contact with each other. For example, if the pillar 150 is Cu—Cu diffusion bonded to the upper plate 111 and the lower plate 112, the upper plate 111 and the lower plate 112 may be coupled in contact with each other.

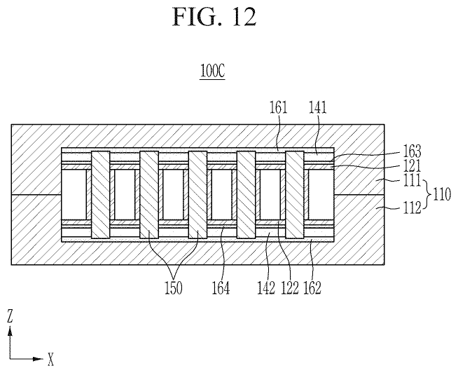

FIG. 12 is a cross-sectional view of a vapor chamber according to an embodiment.

Referring to the drawings, in the vapor chamber 100C, a third adhesive member 163 disposed between a first wick structure 121 and a first deformation prevention structure 141 and a fourth adhesive member 164 disposed between a second wick structure 122 and a second deformation prevention structure 142 may be further included.

The third adhesive member 163 may attach the first wick structure 121 to the first deformation prevention structure 141. A material (for example, a bonding paste, an adhesive, an adhesive film, or the like) having adhesiveness may be used as a material of the third adhesive member 163.

Similarly, the fourth adhesive member 164 may attach the second wick structure 122 to the second deformation prevention structure 142. A material (for example, a bonding paste, an adhesive, an adhesive film, or the like) having adhesiveness may be used as a material of the fourth adhesive member 164.

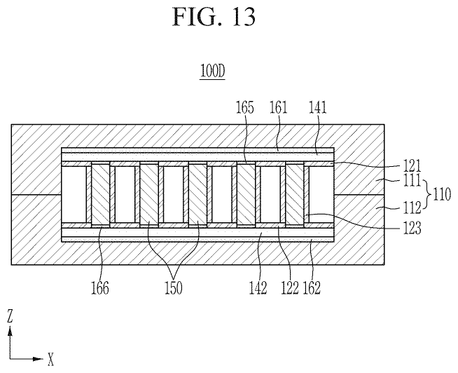

FIG. 13 is a cross-sectional view of a vapor chamber according to an embodiment.

Referring to the drawings, in the vapor chamber 100D, pillars 150 may penetrate a first wick structure 121 and a second wick structure 122, and may not penetrate a first deformation prevention structure 141 and a second deformation prevention structure 142. The pillar 150 may be inserted into a hole of the first wick structure 121 and a hole of the second wick structure 122 to have a structure penetrating the hole of the first wick structure 121 and the hole of the second wick structure 122.

In addition, the vapor chamber 100D may further include a fifth adhesive member 165 disposed between the first deformation prevention structure 141 and the pillar 150 and a sixth adhesive member 166 disposed between the second deformation prevention structure 142 and the pillar 150.

The fifth adhesive member 165 may be exposed through the hole of the first wick structure 121, and the sixth adhesive member 166 may be exposed through the hole of the second wick structure 122. Accordingly, the pillar 150 may be attached and fixed to the fifth adhesive member 165 exposed through the hole of the first wick structure 121 and the sixth adhesive member 166 exposed through the hole of the second wick structure 122.

The fifth adhesive member 165 may attach the first deformation prevention structure 141 to the pillar 150. A material (for example, a bonding paste, an adhesive, an adhesive film, or the like) having adhesiveness may be used as a material of the fifth adhesive member 165.

Similarly, the sixth adhesive member 166 may attach the second deformation prevention structure 142 to the pillar 150. A material (for example, a bonding paste, an adhesive, an adhesive film, or the like) having adhesiveness may be used as a material of the sixth adhesive member 166.

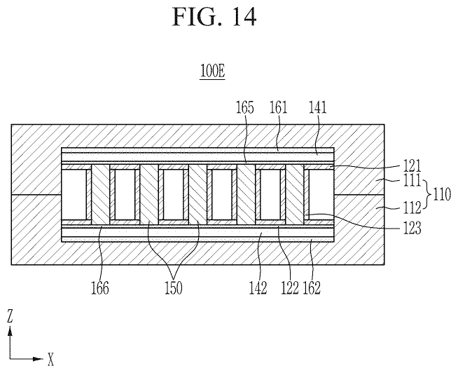

FIG. 14 is a cross-sectional view of a vapor chamber according to an embodiment.

Referring to the drawings, in the vapor chamber 100E, a fifth adhesive member 165 may be extended to be disposed between a first deformation prevention structure 141 and a first wick structure 121, and a sixth adhesive member 166 may be extended to be disposed between a second deformation prevention structure 142 and a second wick structure 122.

The fifth adhesive member 165 may attach not only a pillar 150 but also the first wick structure 121 to the first deformation prevention structure 141, and the sixth adhesive member 166 may attach not only the pillar 150 but also the second wick structure 122 to the second deformation prevention structure 142.

FIG. 15 is a cross-sectional view of a vapor chamber according to an embodiment.

An upper plate 111 and a lower plate 112 of the vapor chamber 100F may have different shapes. For example, the lower plate 112 may have a wider width along each of the X-direction (X) and the Y-direction (Y) than that of the upper plate 111, and the upper plate 111 and the lower plate 112 may constitute a hat-type housing 110. However, FIG. 15 describes another exemplary shape of the vapor chamber, and a shape of the vapor chamber according to the present disclosure may not be limited to the shapes shown in the drawings.

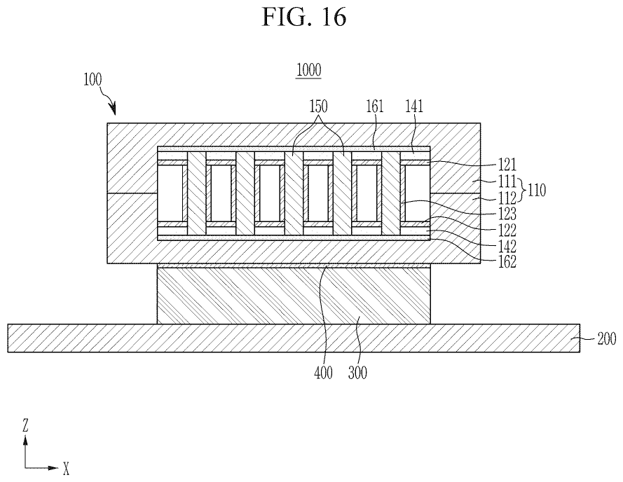

FIG. 16 is a cross-sectional view of a semiconductor package according to an embodiment.

The semiconductor package 1000 may include a substrate 200, a semiconductor chip 300, a vapor chamber 100, and a thermal interface material 400.

The vapor chamber 100 may be disposed above the semiconductor chip 300. The vapor chamber 100 may be any one of the vapor chambers 100A, 100B, 100C, 100D, 100E, and 100F according to the present disclosure.

The substrate 200 may be any one of substrates used in a semiconductor package field, and for example, the substrate 200 may be a printed circuit board, a redistribution substrate, an interposer substrate, or the like. In addition to the semiconductor chip 300, another component may be disposed on the substrate 200.

The semiconductor chip 300 may be disposed on the substrate 200, and may be electrically connected to the substrate 200. A type of the semiconductor chip 300 is not particularly limited, and the semiconductor chip 300 may be a logic chip, a memory chip (e.g., a DRAM, an SRAM, a flash memory, a ROM, an HBM, or the like), a CPU, a GPU, a system on chip (SOC), an application processor (AP) chip, or the like.

The thermal interface material 400 may be disposed between the semiconductor chip 300 and the vapor chamber 100. The thermal interface material 400 may attach the semiconductor chip 300 to the vapor chamber 100, and may function as a heat transfer path between the semiconductor chip 300 and the vapor chamber 100. For example, the thermal interface material 400 may have a paste type, a sheet type, or an adhesive type.

According to the present disclosure, thermal deformation of the vapor chamber 100 may be prevented by introducing deformation prevention structures 141 and 142, and contact interfaces between the vapor chamber 100, the thermal interface material 400, and the semiconductor chip 300 may be maintained flat. In addition, a heat dissipation characteristic of the semiconductor package may be improved by minimizing a heat resistance caused by collected air, and performance of the semiconductor package may be improved by increasing an allowable power of the semiconductor package. In addition, a stress applied to the semiconductor chip may be reduced by reducing thermal deformation of the vapor chamber 100 so that a damage such as a crack of the semiconductor chip is prevented and reliability is secured.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

In addition, the embodiments of the present disclosure are not independent of each other, and may be implemented in combination with each other unless otherwise contradictory. Accordingly, the combined embodiments should also be considered to be included in the present disclosure.

What is claimed is:

1. A vapor chamber comprising:
a housing comprising an upper plate and a lower plate coupled to the upper plate;
a first wick structure on an inner upper surface of the upper plate;
a second wick structure on an inner lower surface of the lower plate;
a first deformation prevention structure between the upper plate and the first wick structure;
a second deformation prevention structure between the lower plate and the second wick structure; and
a pillar inside the housing, wherein the pillar penetrates the first wick structure, the second wick structure, the first deformation prevention structure, and the second deformation prevention structure.

2. The vapor chamber of claim 1, wherein a Young's modulus of each of the first deformation prevention structure and the second deformation prevention structure is greater than a Young's modulus of each of the upper plate and the lower plate.

3. The vapor chamber of claim 1, wherein a thermal conductivity of each of the first deformation prevention structure and the second deformation prevention structure is 80% or more of a thermal conductivity of each of the upper plate and the lower plate.

4. The vapor chamber of claim 1, wherein each of the first deformation prevention structure and the second deformation prevention structure comprise silicon carbide (SiC).

5. The vapor chamber of claim 1, wherein a thickness of the first deformation prevention structure is 50% to 100% of a thickness of a portion of the upper plate corresponding to the inner upper surface of the upper plate, and a thickness of a portion of the second deformation prevention structure is 50% to 100% of a thickness of the lower plate corresponding to the inner lower surface of the lower plate.

6. The vapor chamber of claim 1, wherein a thickness of each of the first deformation prevention structure and the second deformation prevention structure is 0.25 mm to 2 mm.

7. The vapor chamber of claim 1, further comprising:
a first adhesive member between the upper plate and the first deformation prevention structure; and
a second adhesive member between the lower plate and the second deformation prevention structure.

8. The vapor chamber of claim 7,
wherein the upper plate comprises a plurality of first protruding portions protruding in a direction away from the upper plate and toward the lower plate,
wherein the first deformation prevention structure comprises a plurality of second protruding portions protruding in a direction away from the lower plate and toward the upper plate,
wherein each of the plurality of second protruding portions is between first protruding portions from among the plurality of first protruding portions,
wherein the lower plate comprises a plurality of third protruding portions protruding in the direction away from the lower plate and toward the upper plate,
wherein the second deformation prevention structure comprises a plurality of fourth protruding portions protruding in the direction away from the upper plate and toward the lower plate, and
wherein each of the plurality of fourth protruding portions is between third protruding portions from among the plurality of third protruding portions.

9. The vapor chamber of claim 7, wherein at least a portion of the first adhesive member is between the upper plate and the pillar, and at least a portion of the second adhesive member is between the lower plate and the pillar.

10. The vapor chamber of claim 9,
wherein the first adhesive member surrounds a region of a side surface of the pillar adjacent to one end portion of the pillar, and
wherein the second adhesive member surrounds a region of the side surface of the pillar adjacent to another end portion of the pillar opposite to the one end portion.

11. The vapor chamber of claim 1, wherein one end portion of the pillar is in contact with the upper plate, and another end portion of the pillar is in contact with the lower plate.

12. The vapor chamber of claim 1, further comprising:
a third adhesive member between the first wick structure and the first deformation prevention structure; and
a fourth adhesive member between the second wick structure and the second deformation prevention structure.

13. The vapor chamber of claim 1, further comprising a third wick structure that surrounds a side surface of the pillar at a level between the first wick structure and the second wick structure.

14. A vapor chamber comprising:
a housing comprising an upper plate and a lower plate coupled to the upper plate;
a first wick structure on an inner upper surface of the upper plate;
a second wick structure on an inner lower surface of the lower plate;
a first deformation prevention structure between the upper plate and the first wick structure;
a second deformation prevention structure between the lower plate and the second wick structure;
a pillar inside the housing, wherein the pillar penetrates the first wick structure and the second wick structure;
a first adhesive member between the first deformation prevention structure and the pillar; and
a second adhesive member between the second deformation prevention structure and the pillar.

15. The vapor chamber of claim 14, wherein a Young's modulus of each of the first deformation prevention structure and the second deformation prevention structure is greater than a Young's modulus of each of the upper plate and the lower plate.

16. The vapor chamber of claim 14, wherein a thermal conductivity of each of the first deformation prevention structure and the second deformation prevention structure is 80% or more of a thermal conductivity of each of the upper plate and the lower plate.

17. The vapor chamber of claim 14, wherein at least a portion of the first adhesive member is between the first deformation prevention structure and the first wick structure, and at least a portion of the second adhesive member is between the second deformation prevention structure and the second wick structure.

18. A semiconductor package comprising:
a substrate;
a semiconductor chip on the substrate and connected to the substrate;
a vapor chamber on the semiconductor chip; and
a thermal interface material between the semiconductor chip and the vapor chamber,
wherein the vapor chamber comprises:
a housing comprising an upper plate and a lower plate coupled to the upper plate;
a first wick structure on an inner upper surface of the upper plate;
a second wick structure on an inner lower surface of the lower plate;
a first deformation prevention structure between the upper plate and the first wick structure;
a second deformation prevention structure between the lower plate and the second wick structure;
a pillar inside the housing, wherein the pillar is extends from the upper plate to the lower plate and penetrates at least the first wick structure and the second wick structure; and
a third wick structure that surrounds a side surface of the pillar at a level between the first wick structure and the second wick structure.

19. The semiconductor package of claim 18, wherein a thickness of the first deformation prevention structure is 50% to 100% of a thickness of a portion of the upper plate corresponding to the inner upper surface of the upper plate, and a thickness of a portion of the second deformation prevention structure is 50% to 100% of a thickness of the lower plate corresponding to the inner lower surface of the lower plate.

20. The semiconductor package of claim 18, wherein a thickness of each of the first deformation prevention structure and the second deformation prevention structure is 0.25 mm to 2 mm.
